(19) United States
(12) Patent Application Publication
(10) Pub. No.: US 2014/0209890 A1
(43) Pub. Date: Jul. 31, 2014

(54) ORGANIC ELECTROLUMINESCENT LIGHTING DEVICE AND METHOD FOR MANUFACTURING SAME

(71) Applicant: PANASONIC CORPORATION, Osaka (JP)

(72) Inventors: Toshihiko Sato, Osaka (JP); Shintaro Hayashi, Hyogo (JP); Junichi Hozumi, Hyogo (JP)

(73) Assignee: PANASONIC CORPORATION, Osaka (JP)

(21) Appl. No.: 14/342,026

(22) PCT Filed: Dec. 14, 2012
(86) PCT No.: PCT/JP2012/082502

§ 371 Date: Feb. 28, 2014

(30) Foreign Application Priority Data
Dec. 16, 2011 (JP) 2011-276038

(51) Int. Cl. H01L 51/52; H01L 51/56

(52) U.S. Cl. CPC H01L 51/5212; H01L 51/5228; H01L 51/56
USPC 257/40; 438/46

(57) ABSTRACT

An organic electroluminescent lighting device includes an organic electroluminescent element which has a first electrode, a light-emitting layer, and a second electrode, which is formed on a surface of a base substrate and which is sealed with an opposed substrate. The organic electroluminescent lighting device further includes an auxiliary electrode that includes a transparent conductive layer made of optically-transparent electrode material, a conductive resin layer made of electric conductive resin, and a metal film layer made of metal having higher electric conductivity than that of the material of the transparent conductive layer, which are stacked in this order on the surface of the base substrate. The auxiliary electrode is formed on the surface of the base substrate so as to be across an opening edge of the opposed substrate. The auxiliary electrode is formed with a block structure configured to block moisture permeation through the conductive resin layer from outside.

### TECHNICAL FIELD

The invention relates to an organic electroluminescent lighting device with an organic electroluminescent element, and a method for manufacturing the organic electroluminescent lighting device.

### BACKGROUND ART

There has been known an organic electroluminescent lighting device (hereinafter called “an organic EL lighting device”) which includes an organic electroluminescent element (hereinafter called “an organic EL element”) as a planar lighting element (for example, see Japanese Patent No. 4432143).

In the organic EL lighting device, because an electrode thereof is formed of a transparent conductive film or the like having a relatively high specific resistance (electric resistivity), many ideas have been studied for enhancing electric conductivity of the electrode. As an example, it has been known to provide an auxiliary electrode to the electrode. In this configuration, the organic EL element is provided with an extracted part extended from the electrode and designed to feed power to the electrode from an outside, and the auxiliary electrode is formed on the extracted part. The auxiliary electrode is designed to assist electric conduction of the transparent conductive film having a high specific resistance. For example, International Publication No. 2008/062645 discloses a joint terminal made of metal which is formed on a periphery of an anode.

The auxiliary electrode is usually formed by a dry film formation process. However, this process requires a high cost. Thus, there is a large advantage in production of an auxiliary electrode by a wet film formation process (e.g., by plating) or a printing process, because there processes are less costly. However, it has been known that, in a case where the auxiliary electrode is formed on a surface of the transparent conductive film by a film formation process or a printing process, the adhesion of the auxiliary electrode tends to be insufficient.

For improving the adhesion, the auxiliary electrode may be formed of: a resin layer formed on a surface of a transparent conductive film; and a metal layer formed on a surface of the resin layer. However, in this configuration, moisture will easily intrude inside the device through the resin layer as a moisture penetration pathway, and the organic EL element will be easily deteriorated. Described in detail, an organic EL element is usually sealed in a space enclosed by a pair of substrates opposed to each other in order to avoid deterioration caused of moisture. However, if a resin layer is provided at a bonded region between the pair of substrates, there is a concern about moisture permeation through the resin layer.

### DISCLOSURE OF INVENTION

The invention has been developed in view of above circumference, and an object thereof is to provide an organic electroluminescent lighting device capable of blocking moisture permeation into an organic electroluminescent element as well as stably improving electric conductivity of an electrode.

An organic electroluminescent lighting device according to the invention includes: a base substrate; an organic electroluminescent element formed on a surface of the base substrate, the organic electroluminescent element including an optically-transparent first electrode, a light-emitting layer, and a second electrode facing the first electrode with the light-emitting layer interposed therebetween; and an opposed substrate, the organic electroluminescent element formed on the surface of the base substrate being sealed with the opposed substrate which has a concave portion in a center thereof and which is placed opposite to the base substrate. The organic electroluminescent lighting device further includes an auxiliary electrode which is formed on the surface of the base substrate so that the auxiliary electrode lies on both sides of an opening edge of the opposed substrate. The auxiliary electrode includes a transparent conductive layer made of optically-transparent electrode material, a conductive resin layer made of electric conductive resin, and a metal film layer made of metal having higher electric conductivity than that of the material of the transparent conductive layer, which are stacked in this order on the surface of the base substrate. The auxiliary electrode is formed with a block structure configured to block moisture permeation through the conductive resin layer into the organic electroluminescent element from outside.

In the organic electroluminescent lighting device, it is preferable that the opposed substrate is formed of a plate member shaped like a planar plate and a lateral wall member which is made of resin and prepared separately from the plate member, so that the concave portion is formed between the plate member and the lateral wall member.

In the organic electroluminescent lighting device, it is preferable that the block structure has a structure in which the metal layer is formed so as to cover at least one lateral of the conductive resin layer or a structure in which each of the metal layer and the conductive resin layer is divided by the opening edge of the opposed electrode.

In the organic electroluminescent lighting device, it is preferable that an electrode terminal is formed on a rear side of the opposed substrate, the electrode terminal is connected with the metal film layer through a side conductor formed on a lateral of the opposed substrate, and the side conductor includes an adhesion layer.

In the organic electroluminescent lighting device, it is preferable that the opposed substrate is formed, on an edge of the rear side of the opposed substrate, with a chamfered structure so as to moderate an angle of the edge.

A method for manufacturing the organic electroluminescent lighting device according to the invention includes a step of forming the auxiliary electrode that includes: a resin layer application step of applying the material of the conductive resin layer to the transparent conductive layer formed on the base substrate so that the material is applied to a region where the auxiliary electrode is to be formed, thereby forming the conductive resin layer; and a metal film plating step of forming the metal film layer, by plating, on a surface of the conductive resin layer.

According to the invention, it is possible to provide an organic electroluminescent lighting device capable of blocking moisture permeation into an organic electroluminescent element as well as stably improving electric conductivity of an electrode.

### BRIEF DESCRIPTION OF DRAWINGS

FIG. 1 is a sectional view of an organic electroluminescent lighting device according to a first embodiment of the invention;

FIG. 2 is a sectional view of an organic electroluminescent lighting device according to a second embodiment of the invention;

FIGS. 3A to 3F are views illustrating a process of forming an auxiliary electrode in the organic electroluminescent lighting device according to the first embodiment, where FIGS. 3A, 3C and 3E are perspective views and FIGS. 3B, 3D and 3F are sectional views;

FIGS. 4A to 4F are views illustrating a process of forming an auxiliary electrode in the organic electroluminescent lighting device according to the second embodiment, where FIGS. 4A, 4C and 4E are planar views and FIGS. 4B, 4D and 4F are sectional views;

FIG. 5 is a sectional view of an organic electroluminescent lighting device according to a third embodiment of the invention;

FIG. 6 is a sectional view of an organic electroluminescent lighting device according to a fourth embodiment of the invention;

FIGS. 7A to 7C are views illustrating chamfered structures regarding organic electroluminescent lighting devices according to the fourth embodiment; and

FIG. 8 is a view illustrating a chamfered structure regarding an organic electroluminescent lighting device according to the fourth embodiment.

### DESCRIPTION OF EMBODIMENT

### First Embodiment

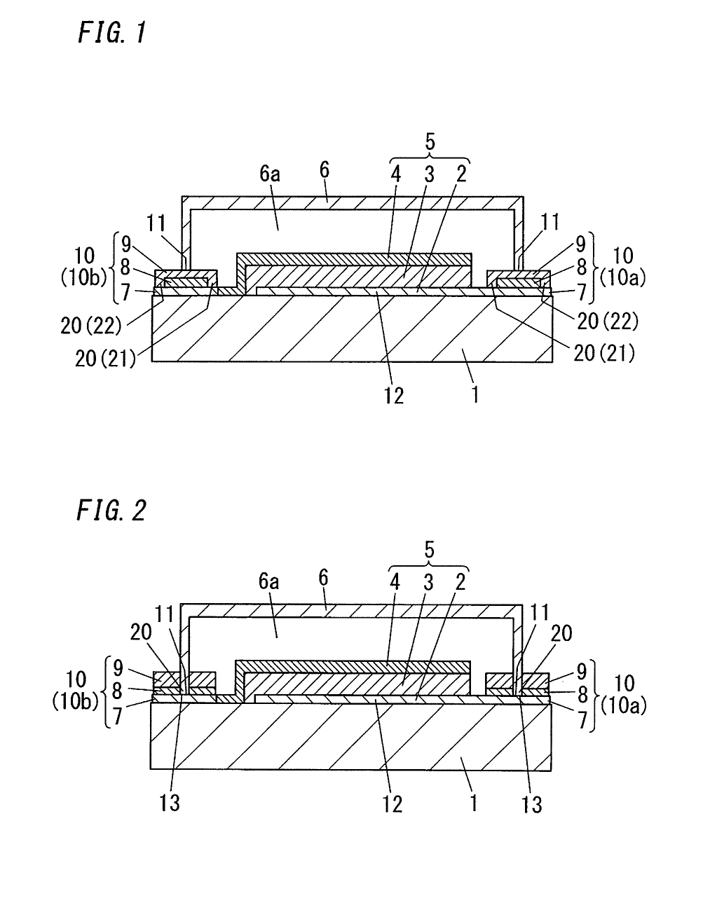

FIG. 1 shows an organic electroluminescent lighting device (an organic EL lighting device) according to an embodiment. The organic EL lighting device includes an organic electroluminescent element 5 (an organic EL element 5) which has an optically-transparent first electrode 2, a light-emitting layer 3, and a second electrode 4 facing the first electrode 2 with the light-emitting layer 3 interposed therebetween. The organic EL element 5 is formed on a surface of a base substrate 1 and is sealed with an opposed substrate 6 which has a concave portion 6a in a center thereof and which is placed opposite to the base substrate 1. The concave portion 6a of the opposed substrate 6 has a dimension larger than that of the organic EL element 5. An opening edge 11 of the opposed substrate 6 is bonded to the base substrate 1 so that the organic EL element 5 is housed in the opposed substrate 6. Typically, the organic EL element 5 is designed so that the first electrode 2 (which is an electrode having optically transparent property) functions as an anode and the second electrode 4 functions as a cathode, but the polarities may be reversed.

The light-emitting layer 3 of the organic EL element 5 is a layer in which holes injected through the anode (the first electrode 2) and electrons injected through the cathode (the second electrode 4) are recombined to emit light. The light-emitting layer 5 has a luminescence material layer containing luminescence material. The light-emitting layer 5 may further include proper layer(s) selected from a group consisting of a hole-injection layer, a hole-transport layer, an electron-transport layer, an electron-injection layer, and an intermediate layer or a functional layer configured to assist light-emission or charge-transportation.

The base substrate 1 is an optically-transparent substrate, and may be made of glass, moisture-proof resin, or the like. The opposed substrate 6 may be also made of glass, moisture-proof resin, or the like. Each of the base substrate 1 and the opposed substrate 6 is made of insulating material. In view of effectively suppressing moisture permeation, each of the base substrate 1 and the opposed substrate 6 is preferably made of glass. Examples of the glass include a high-refractive index glass and a soda glass. In the configuration shown in FIG. 1, the opposed substrate 6 is formed into a shape having a square bracket in cross-section. For example, a cover glass can be used for the opposed substrate 6.

Auxiliary electrodes 10 are formed on the surface of the base substrate 1 (on a first surface of the base substrate 1; on an upper surface thereof in FIG. 1) so that each of the auxiliary electrodes 10 is across an opening edge 11 of the opposed substrate 6. The auxiliary electrode 10 has a function to assist electric conduction of an electrode. Thus, the auxiliary electrode 10 has higher electric conductivity than that of the first electrode 2. Each of the auxiliary electrodes 10 is formed so as to extend outside the opposed substrate 6. With this configuration, the auxiliary electrode can be easily connected to an external power source, and thus functions as an electrode pad for power feeding to the electrode. Each of the auxiliary electrodes 10 is also formed so as to extend inside (a side of the organic EL element 5) the opposed substrate 6. Each of the auxiliary electrodes 10 is extended so as to be close to a region of an electrode of the organic EL element 5 inside the device, and thus can further improve the effect of assistance for electric conduction.

As shown in FIG. 1, each of the auxiliary electrodes 10 includes a transparent conductive layer 7 made of optically-transparent electrode material, a conductive resin layer 8 made of electric conductive resin, and a metal film layer 9 made of metal having higher electric conductivity than that of the material of the transparent conductive layer 7, which are stacked in this order. Because the metal film layer 9 is adhered to the transparent conductive layer 7 by use of resin, the metal film layer 9 can be adhered to the base substrate 1 side with high adhesion. Explained in detail, in a case where the metal film layer 9 is formed by a wet process as in a conventional configuration, there is a concern that the metal film layer 9 is fallen away due to insufficient adhesion between the metal film layer 9 and the transparent conductive layer 7. On the other hand, since the metal film layer 9 is adhered to the transparent conductive layer 7 with the conductive resin layer 8, adhesion thereof can be improved in the embodiment. In addition, since the conductive resin layer 8 of the embodiment has electric conductivity, the conductive resin layer 8 does not disturb the effect of assistance for electric conduction. Accordingly, the auxiliary electrode 10 having superior adhesion and superior effect of assistance for electric conduction can be realized. That is, in the embodiment, electric conductivity can be stably improved because the metal film layer 9 is adhered by the conductive resin layer 8.

The auxiliary electrode 10 is formed with a block structure 20 configured to block moisture permeation through the conductive resin layer 8 into the organic EL element 5 from outside. Since the conductive resin layer 8 is mainly made of resin which has a higher moisture absorptance than that of metal or glass in general, water will easily penetrate through the resin layer. However, the auxiliary electrode 10 is provided with the block structure 20 that blocks moisture from reaching the organic EL element 5, and therefore deterioration of the element can be suppressed.

Preferred aspect of the block structure 20 is a structure in which the metal film layer 9 is formed so as to cover at least one lateral (side) of the conductive resin layer 8. With this configuration, penetration pathway of water can be blocked by the metal film layer 9, because the conductive resin layer 8 is covered with the metal film layer 9 which has a higher moisture blocking property. As a result, it is possible to avoid the penetration of moisture into the device through the conductive resin layer 8.

The block structure 20 of the embodiment has a structure in which both laterals of the conductive resin layer 8 are covered with the metal film layer 9. In other words, a whole of outer surface (i.e., a surface parallel to the base substrate 1 and lateral faces) of the conductive resin layer 8 is covered with the metal film layer 9. In this structure, the metal film layer 9 is formed so as to cover an inner lateral of the conductive resin layer 8, thereby forming an inner cover 21 as an inner part of the block structure 20. In addition, the metal film layer 9 is formed so as to cover an outer lateral of the conductive resin layer 8, thereby forming an outer cover 22 as an outer part of the block structure 20. As described above, the metal film layer 9 is formed so as to cover both laterals of the conductive resin layer 8, namely the block structure 20 is formed on each of the inside and outside. As a result, moisture permeation can be highly blocked.

In the embodiment, the block structure 20 has a structure in which both of the laterals of the conductive resin layer 8 are covered with the metal film layer 9. However, either of the laterals of the conductive resin layer 8 may be covered with the metal film layer 9. Even in this configuration, it is possible to suppress moisture permeation into the organic EL element 5, because the pathway through the conductive resin layer 8 between the inside and outside of the device can be blocked. Even either of them can suppress moisture permeation through the resin layer, because a barrier structure against moisture, provided by the metal film layer 9, is formed between the base substrate 1 and the opposed substrate 6. The organic EL lighting device of the embodiment has an enhanced effect in blocking moisture permeation, because the organic EL element 5 is located in a space enclosed by the base substrate 1, the opposed substrate 6 and the metal film layer 9. In view of enhancing suppression effect of moisture permeation, it is preferable to cover a whole of the lateral, which is located outside of the opposed substrate 6, of the conductive resin layer 8. In this configuration, the conductive resin layer 8 can be prevented from being in direct contact with moisture, because the conductive resin layer 8 is not exposed outward.

The metal film layer 9 is preferably in contact with the transparent conductive layer 7. In a configuration where the metal film layer 9 is in contact with the transparent conductive layer 7, the metal film layer 9 can directly assist electric conduction of the transparent conductive layer 7, and thus to further enhance the effect of assistance for electric conduction. For ease of connection between the metal film layer 9 and the transparent conductive layer 7, the metal film layer 9 is preferably formed to cover the lateral face of the conductive resin layer 8 so that the metal film layer 9 is in contact with the transparent conductive layer 7.

In the embodiment, the whole outer surface of the conductive resin layer 8 is covered with the metal film layer 9 (in other words, the whole outside region of the conductive resin layer 8 is in contact with either the transparent conductive layer 7 or the metal film layer 9). This configuration suppresses moisture permeation into the device through the conductive resin layer 8 as well as directly assists electric conduction of the transparent conductive layer 7 by the metal film layer 9.

As shown in FIG. 1, the block structure 20 in the embodiment is a structure covering the lateral face of the conductive resin layer 8. In the structure of the embodiment, both of the lateral faces of the conductive resin layer 8 are covered with the metal film layer 9. Because the metal film layer 9 is laminated on the surface (the upper surface in FIG. 1) of the conductive resin layer 8, the metal film layer 9 can prevent moisture from permeating to the resin through the surface. However, if the lateral faces of the conductive resin layer 8 are exposed outward, there is a concern about moisture permeation through these lateral faces. In regard to this, the block structure 20 is provided so as to cover the lateral face of the conductive resin layer 8, and therefore moisture permeation can be suppressed.

In the embodiment, the opening edge 11 of the opposed substrate 6 is bonded to a surface of the metal film layer 9. The transparent conductive layer 7, the conductive resin layer 8 and the metal film layer 9 in each auxiliary electrode 10 are each formed continuously so as to be across the opening edge 11 of the opposed substrate 6. That is, each of the auxiliary electrodes 10 is formed on both inside and outside the opposed substrate 6. The metal film layer 9 for assisting electric conduction is formed continuously, and thus can provide higher effect of assistance for electric conduction. The opposed substrate 6 may be bonded to the metal film layer 9 with proper adhesive material. The adhesive material preferably has moisture-proof property, and may be fritted glass.

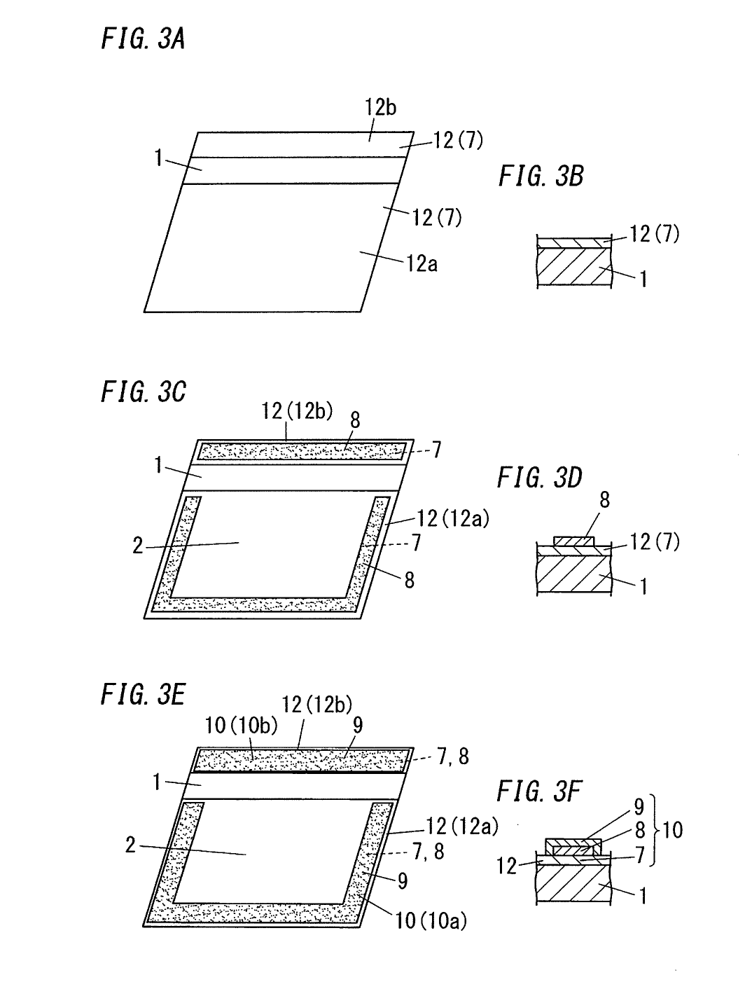

The auxiliary electrodes 10 are preferably formed on a region surrounding the organic EL element 5 so that each of the auxiliary electrodes 10 is formed around the organic EL element 5 in a planar view (in a view seen from a direction perpendicular to the surface of the base substrate 1). Effect of assistance for electric conduction can be enhanced by forming the auxiliary electrode 10 around the organic EL element 5. In a configuration where the auxiliary electrode 10 is formed into a square bracket shape (angulated U-shape) along a periphery of the first electrode 2 (see FIG. 3E), it is possible to further enhance a power feeding efficiently to the first electrode 2. The auxiliary electrodes 10 preferably include: a first auxiliary electrode 10a electrically connected to the first electrode 2; and a second auxiliary electrode 10b electrically connected to the second electrode 4. In this configuration, the second auxiliary electrode 10b functions as an electrode pad for the second electrode 4, and the first auxiliary electrode 10a functions as an electrode pad and also doubles as an assistant for electric conduction of the first electrode 2.

It is preferable that the transparent conductive layers 7 of respective auxiliary electrodes 10 and the first electrode 2 are derived from the same transparent conductive film 12. This configuration makes it easy to form the auxiliary electrodes 10 and the first electrode 2, and thus a manufacturing process of the device can be made easier.

Material of the transparent conductive film 12 from which the transparent conductive layers 7 of the auxiliary electrodes 10 and the first electrode 2 are formed is not particularly limited, so long as it has optical transparency and electro conductivity. Transparent metallic oxide may be used for this material, for example. The transparent conductive film 12 may be a layer made of ITO, IZO, AZO, ZnO, or the like. The thickness of the transparent conductive film 12 (in other words, each thickness of the first electrode 2 and the transparent conductive layers 7) is preferably set to 0.05 μm to 1 μm, or 0.1 μm to 0.5 μm, but is not limited thereto.

Examples of material for forming the conductive resin layer 8 include a polymer resin composition in which electro conductive fillers are contained. The fillers may be formed of metal particles. Examples of the resin include acrylic resin and epoxy resin. It is preferable to interpose a monolayer made of organic material in a boundary between the conductive resin layer 8 and the transparent conductive layer 7. The monolayer has a thickness comparable to a size of molecular, and provides advantages of enhancing adhesion while securing electric conductivity. The thickness of the conductive resin layer 8 is preferably set to 0.1 μm to 1.0 μm, but is not limited thereto.

The metal film layer 9 can be made of proper metal material. In view of productivity, the metal material preferably has a property suitable for plating and has high electric conductivity. Examples of the metal material include Cu and Ni. The thickness of the metal film layer 9 is preferably set to 1.0 μm to 2.0 μm, but is not limited thereto.

The second electrode 4 can be made of proper electrode material. Examples of the electrode material include metal, and particularly Al. In view of enhancing light output of the device, it is preferable to form the second electrode 4 as a reflecting electrode.

A method for manufacturing the organic EL lighting device shown in FIG. 1 is described with reference to FIG. 3. In manufacturing the organic EL lighting device, the auxiliary electrodes 10 are formed before the formation of the light-emitting layer 3 of the organic EL element 5. In the method illustrated in FIG. 3, a step of forming the auxiliary electrodes 10 includes: a resin layer application step of forming the conductive resin layers 8, by application, on the surfaces of respective transparent conductive layers 7; and a metal film plating step of forming the metal film layers 9 on the surfaces of respective conductive resin layers 8 by plating. The resin layer application step is a step of applying the material of the conductive resin layer 8 to the transparent conductive layers 7 formed on the base substrate 1 so that the material is applied to regions where the auxiliary electrodes 10 are to be formed, thereby forming the conductive resin layers 8. The metal film plating step is a step of laminating plating-material on the surfaces of the conductive resin layers 8 by plating, thereby forming the metal film layers 9.

The method illustrated in FIG. 3 will be described in detail. For producing the auxiliary electrodes 10, firstly, prepared is the base substrate 1 on which the transparent conductive film 12 is formed, as shown in FIGS. 3A and 3B. The shape of the transparent conductive film 12 formed on the base substrate 1 is not limited particularly. As shown in FIG. 3A, it is preferred that the transparent conductive film 12 has: a first region 12a for forming the first electrode 2 and the first auxiliary electrode 10a; and a second region 12b for forming the second auxiliary electrode 10b, which are separated from each other. With this configuration, the transparent conductive film 12 is divided into the first region 12a and the second region 12b, and therefore the first auxiliary electrode 10a which is to be connected to the first electrode 2 can be electrically separated from the second auxiliary electrode 10b which is to be connected to the second electrode 4. The transparent conductive film 12 having separated regions can be obtained by removing, using photolithography and etching techniques, a part of the transparent conductive film 12 formed on the whole surface of the base substrate 1, or by forming a mask on a part of the surface of the base substrate 1 and then depositing the material of the transparent conductive film 12 to thereby form the transparent conductive film 12 having the separated regions.

It is preferable to then form a monolayer, by spin coating or the like, on the surface of the transparent conductive film 12 on the base substrate 1. The monolayer may be made of organic compound. For example, polymerizable organic material such as acrylic acid can be used. Film-formability and adhesion of the conductive resin layer 8 can be enhanced by providing the monolayer. The monolayer is preferably formed on at least regions, where the auxiliary electrodes 10 are to be formed, on the surface of the transparent conductive film 12. Alternatively, the monolayer may be formed on the whole surface of the transparent conductive film 12, because it is easy to apply the monolayer to the whole surface. The substrate after application of the material of the monolayer is then subject to a dry process and a cleaning process, and thereby the monolayer is formed on the surface of the transparent conductive film 12. The cleaning process may be water washing using water or proper water solution. Excess amount of the monolayer material can be washed out by the cleaning process, and thus a one-molecule thick layer can be formed preferably. Since the monolayer is a thin layer of the organic material, the monolayer may be deemed as a part of the conductive resin layer 8.

The material of the conductive resin layer 8 is then applied to the surface of the transparent conductive film 12 on the base substrate 1 so that the conductive resin layers 8 have desired shapes for forming the auxiliary electrodes 10, and thereby the conductive resin layers 8 are formed as shown in FIGS. 3C and 3D. In this process, the material of the conductive resin layer 8 is applied to regions, where the auxiliary electrodes 10 are to be formed, on the transparent conductive film 12. The material can be applied by a proper printing process. Examples of the printing process include screen printing, gravure printing, and flexographic printing. With this process, the conductive resin layers 8 can be formed selectively on the regions where the auxiliary electrodes 10 are to be formed. It is notable, in the strict sense, that the conductive resin layers 8 should be formed so that each dimension of the conductive resin layers 8 is a little smaller than a desired dimension of a corresponding auxiliary electrode 10, namely, each width of the conductive resin layers 8 is smaller than that of a corresponding auxiliary electrode 10 by the thickness(es) of the metal film layer 9. With this configuration, the auxiliary electrodes 10 each having the desired dimension (desired width) can be obtained by covering the lateral(s) of the conductive resin layers 8 with the metal film layers 9. Each of the conductive resin layers 8 is preferably formed on an inner region of an outer periphery of the transparent conductive film 12. With this configuration, the transparent conductive film 12 exists at a region outside the outer lateral of the conductive resin layer 8, and thus the lateral of the conductive resin layer 8 can be easily covered with the metal film layer 9 when the metal film layer 9 is formed.

Preferably, the base substrate 1 is then immersed in a catalyst solution for plating. With this process, the catalyst for plating is adhered to the surfaces (the whole of the exposed surfaces) of the conductive resin layers 8. The catalyst solution for plating may be a palladium catalyst solution. Adhesion of the catalyst for plating makes it easy to plate the surfaces of the conductive resin layers 8 with metal, because the catalyst serves as nucleus(nuclei) for plating. Alternatively, the catalyst solution for plating may be applied to regions of the surfaces of the transparent conductive layers 8 on the base substrate 1. After the adhesion of the catalyst for plating, it is subject to a cleaning process by such as water washing using water or proper water solution. Excess amount of the catalyst for plating can be washed out by the cleaning process, and thus the remained catalyst serves as the nuclear(nuclei) for plating. The conductive resin layer 8 is made of material containing polymer resin, and thus has a higher adhesion to the catalyst than that the transparent conductive film 12 has. Accordingly, a larger amount of the catalyst for plating can be adhered to the conductive resin layer 8, and thus a plating layer can be easily formed on the surfaces of the conductive resin layers 8 by the plating.

The metal film layers 9 are then formed on the surfaces of the conductive resin layers 8 on the base substrate 1 by plating. The plating is preferably performed based on electroless plating by immersing the base substrate 1 in a plating solution. The plating may be copper plating or nickel plating, but is not limited thereto. After a cleaning process of the plated substrate, the auxiliary electrodes 10 each having the transparent conductive layer 7, the conductive resin layer 8 and the metal film layer 9 as shown in FIGS. 3E and 3F can be obtained. The cleaning process may be water washing using water or proper water solution. The cleaning process preferably includes acid treatment. Unwanted material and layer, such as the monolayer, which are adhered on the surface of the transparent conductive film 12 (i.e., adhered on a region other than the auxiliary electrodes 10) can be removed by the acid treatment.

As shown in FIG. 3F, each of the metal film layers 9 formed by plating covers the whole surface of a corresponding conductive resin layer 8. The catalyst for plating is adhered to the whole exposed surface of the conductive resin layers 8, namely, is adhered not only to the surface of each conductive resin layer 8 parallel to the surface of the base substrate 1 but also to the lateral faces thereof. As a result, each of the metal film layers 9 formed by the plating is formed on the surface and the lateral faces of a corresponding conductive resin layer 8 so as to cover the whole of the conductive resin layer 8. Note that, even in a case where the catalyst for plating is not adhered to a lateral face of the conductive resin layer 8, the plating layer formed on the surface of the conductive resin layer 8 gradually extends toward the lateral of the conductive resin layer 8 across over an edge of the surface. As a result, it is possible to form the auxiliary electrode 10 so that the conductive resin layer 8 is covered with the metal film layer 9.

Then, the organic EL element 5 is formed after formation of the auxiliary electrodes 10. The organic EL element 5 is formed by laminating the light-emitting layer 3 and the second electrode 4 on a center region of the transparent conductive film 12, where the center region of the transparent conductive film 12 serves as the first electrode 2. Each component of the organic EL element 5 may be formed by a proper film formation process such as evaporation or application. These components should be avoided from being formed on the regions of the auxiliary electrodes 10. In view of preventing short-circuit, the light-emitting layer 3 is formed so that an end line of the first electrode 2 on the second auxiliary electrode 10b side is covered with the light-emitting layer 3 (see FIG. 1). In addition, the second electrode 4 is formed so as to extend outward from an end line of the light-emitting layer 3 on the second auxiliary electrode 10b side, and is in contact and electrically connected with the second auxiliary electrode 10b. The second electrode 4 may be formed by depositing metal material such as Al.

Finally, the opening edge 11 of the opposed substrate 6 is bonded to the surfaces of the metal film layers 9 of the auxiliary electrodes 10 so that the organic EL element 5 is housed in the concave portion 6a of the opposed substrate 6. The opposed substrate 6 can be bonded with proper adhesive material. The adhesive material preferably has moisture-proof property, and may be fritted glass. It is notable that, in a region of the base substrate 1 where the auxiliary electrodes 10 are not formed, the opening edge 11 of the opposed substrate 6 is bonded to the transparent conductive film 12 or directly to the base substrate 1, and thus there is a concern that a gap may be generated between the opposed substrate 6 and the base substrate 1 (and between the opposed substrate 6 and the transparent conductive film 12) caused of absence of the auxiliary electrode 10. In the embodiment, the gap is preferably filled with the adhesive material. The concave portion 6a of the opposed substrate 6 may be filled with a sealant resin so as to encapsulate the organic EL element 5. In this configuration, the opposed substrate 6 may be bonded with the sealant resin.

The organic EL lighting device of the embodiment shown in FIG. 1 can be obtained with the above described method. The organic EL lighting device manufactured by the above described method has advantages that: electric conductivity can be improved by the auxiliary electrode 10; the metal film layer 9 can be tightly adhered by the conductive resin layer 8; and moisture permeation into the organic EL element 5 can be blocked by the block structure 20.

Note that the second electrode 4 may be formed so that an end of the second electrode 4 is extended to the outside of the opposed substrate 6 to form an electrode pad. In other words, the auxiliary electrode 10 may not include the second auxiliary electrode 10b, and the second electrode 4 may be formed on the base substrate 1 so that the second electrode 4 is extended across the opening edge 11 of the opposed substrate 6.

### Second Embodiment

FIG. 2 shows an organic EL lighting device according to an embodiment. The organic EL lighting device has the substantially same configuration with that shown in FIG. 1 (the lighting device according to the first embodiment) except for the structure in the auxiliary electrode 10. The auxiliary electrodes 10 in the embodiment are also formed on a surface of a base substrate 1 so that each of the auxiliary electrodes 10 is across an opening edge 11 of an opposed substrate 6. Each of the auxiliary electrodes 10 includes a transparent conductive layer 7 made of optically-transparent electrode material, a conductive resin layer 8 made of electric conductive resin, and a metal film layer 9 made of metal having higher electric conductivity than that of the material of the transparent conductive layer 7, which are stacked in this order. Because the metal film layer 9 is adhered to the transparent conductive layer 7 by use of resin, the metal film layer 9 can be adhered to the base substrate 1 side with high adhesion. Since the metal film layer 9 is adhered to the transparent conductive layer 7 with the conductive resin layer 8, adhesion thereof can be improved in the embodiment. In addition, since the conductive resin layer 8 has electric conductivity, the conductive resin layer 8 does not disturb the effect of assistance for electric conduction. Accordingly, the auxiliary electrodes 10 having superior adhesion and superior effect of assistance for electric conduction can be realized. The auxiliary electrode 10 may be formed into the same shape with the embodiment of FIG. 1 (i.e., the first embodiment) in a planar view.

In the embodiment, a block structure 20 configured to block moisture permeation through the conductive resin layer 8 into the organic EL element 5 from outside is a structure in which each laminate of the metal film layer 9 and the conductive resin layer 8 is divided by the opening edge 11 of the opposed substrate 6. With this configuration, each conductive resin layer 8 is formed discontinuously with divided by the opening edge 11 of the opposed substrate 6, and thus moisture can be prevented from penetrating through the conductive resin layer 8 to the organic EL element 5. Accordingly, deterioration of the element can be prevented. In detail, an inner part of each conductive resin layer 8 located inside the opposed substrate 6 is covered with the opposed substrate 6 having a higher moisture blocking property, and thus the inner part of each conductive resin layer 8 can be prevented from being exposed to moisture. As a result, it is possible to avoid the penetration of moisture into the device through the conductive resin layer 8. In the embodiment, a laminate of the metal film layer 9 and the conductive resin layer 8 formed on a surface of the transparent conductive layer 7 is divided by the opposed substrate 6, and the opposed substrate 6 is bonded to the surface of the transparent conductive layer 7. Since there is no conductive resin layer 8 between the base substrate 1 and the opposed substrate 6, it is possible to suppress moisture permeation through resin.

In the embodiment, each laminate of the metal film layer 9 and the conductive resin layer 8 is divided by a substrate insertion groove 13. The opening edge 11 of the opposed substrate 6 is inserted in the substrate insertion grooves 13, and is bonded to the surfaces of the transparent conductive layers 7. The opposed substrate 6 may be bonded to the transparent conductive layer 7 with proper adhesive material. Each width of the substrate insertion grooves 13 preferably is the same as or a little larger than a thickness of the opening edge 11 of the opposed substrate 6. Note that the width of the substrate insertion groove 13 is preferably as small as possible, because a large width of the substrate insertion groove 13 may deteriorate an effect of assistance for electric conduction. It is preferable that each lateral surface of the substrate insertion groove 13 is in contact with a lateral surface of the opening edge 11 of the opposed substrate 6. In other words, it is preferable that the opening edge 11 of the opposed substrate 6 is clamped by the substrate insertion groove 13.

As shown in FIG. 2, each of the auxiliary electrodes 10 is across the opening edge 11 of the opposed substrate 6 so that the transparent conductive layer 7 is formed continuously and the laminate of the conductive resin layer 8 and the metal film layer 9 is divided by the opening edge 11 of the opposed substrate 6. With this configuration, each of the auxiliary electrodes 10 is formed on both of the inside and outside of the opposed substrate 6. As a result, an outer part of the auxiliary electrode 10 functions as an electrode pad. In addition, an inner part of the auxiliary electrode 10 can be extended so as to be close to a region of an electrode of the organic EL element 5, and thus can further improve the effect of assistance for electric conduction.

As shown in FIG. 2, the block structure 20 in the embodiment is a structure covering a lateral face of the conductive resin layer 8. In the structure of the embodiment, an outer lateral face of the inner part of the conductive resin layer 8 is covered with opposed substrate 6. Because the metal film layer 9 is laminated on a surface (the upper surface in FIG. 2) of the conductive resin layer 8, the metal film layer 9 can prevent moisture from permeating to the resin through the surface. However, if the lateral faces of the conductive resin layer 8 are exposed outward, there is a concern about moisture permeation through these lateral faces. In regard to this, the block structure 20 is provided so as to cover the lateral face of the conductive resin layer 8, and therefore moisture permeation can be suppressed.

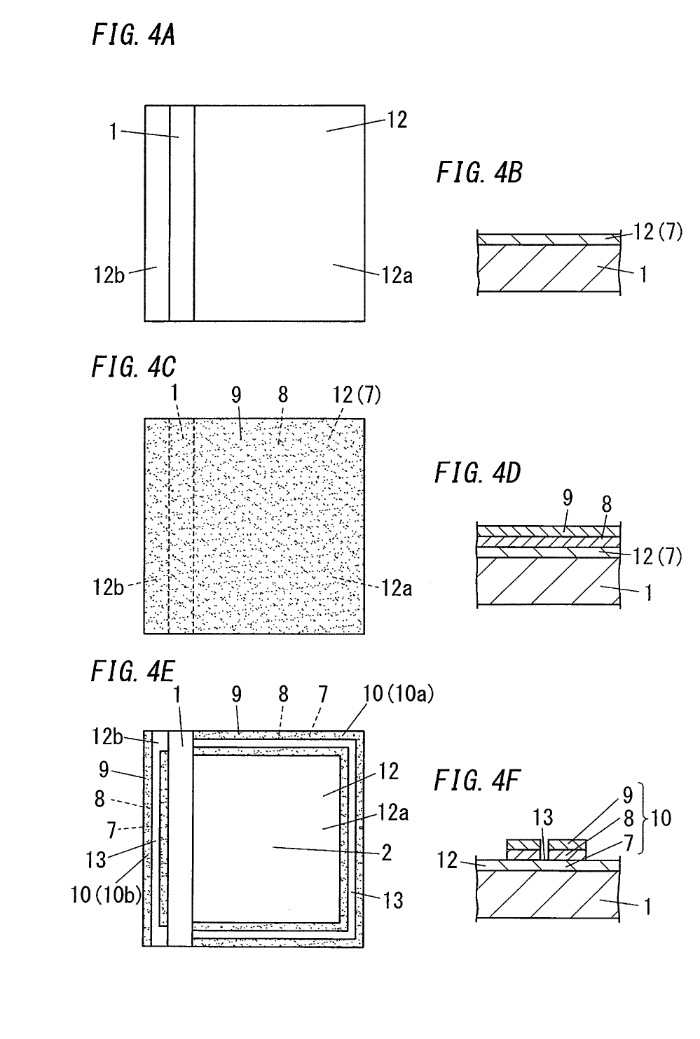

A method for manufacturing the organic EL lighting device shown in FIG. 2 is described with reference to FIG. 4. As similar to the method illustrated in FIG. 3, in manufacturing the organic EL lighting device, the auxiliary electrodes 10 are formed before the formation of the light-emitting layer 3 of the organic EL element 5. In the method illustrated in FIG. 4, a step of forming the auxiliary electrodes 10 includes: a resin layer application step of forming, by application, the conductive resin layers 8 on the surfaces of respective transparent conductive layers 7; and a metal film plating step of forming the metal film layers 9 on the surfaces of respective conductive resin layers 8 by plating. In the method illustrated in FIG. 4, a conductive resin layer 8 and a metal film layer 9 are formed on the whole surface area of a transparent conductive film 12. A part, which corresponds to a region other than the auxiliary electrodes 10, of each of the conductive resin layer 8 and the metal film layer 9 is then removed, thereby obtaining the auxiliary electrodes 10 in which each of the conductive resin layer 8 and the metal film layer 9 is divided.

The method illustrated in FIG. 4 will be described in detail. For producing the auxiliary electrodes 10, firstly, prepared is the base substrate 1 on which the transparent conductive film 12 is formed as shown in FIGS. 4A and 4B. The base substrate 1 on which the transparent conductive film 12 is formed can be formed like the embodiment of FIG. 3 (first embodiment).

It is preferable to then form a monolayer, by spin coating or the like, on the surface of the transparent conductive film 12 on the base substrate 1. The monolayer may be made of organic compound, such as acrylic acid. Film-formability and adhesion of the conductive resin layer 8 can be enhanced by providing the monolayer. The monolayer is formed on the whole surface of the transparent conductive film 12. Alternatively, the monolayer may be formed on at least regions, where the auxiliary electrodes 10 are to be formed, on the surface of the transparent conductive film 12. Note that it is easier to apply the monolayer to the whole surface. The substrate after application of the material of the monolayer is then subject to a dry process and a cleaning process, and thereby the monolayer is formed on the surface of the transparent conductive film 12. The cleaning process may be water washing using water or proper water solution. Excess amount of the monolayer material can be washed out by the cleaning process, and thus a one-molecule thick layer can be formed preferably.

The material of the conductive resin layer 8 is then applied to the whole surface of the transparent conductive film 12 on the base substrate 1, thereby forming a conductive resin layer 8. The material of the conductive resin layer 8 can be applied by a proper printing process. Alternatively, the conductive resin layer 8 can be formed by immersing the base substrate 1 in a solution containing resin. It is easy to form the conductive resin layer 8, because the conductive resin layer 8 is formed not to have a pattern shape but to be on the whole surface of the substrate.

Preferably, the base substrate 1 is then immersed in a catalyst solution for plating. With this process, the catalyst for plating is adhered to the surfaces (the whole of the exposed surfaces) of the conductive resin layers 8. The process of immersing the catalyst for plating can be like the process of FIG. 3 (first embodiment).

A metal film layer 9 is then formed on a surface of the conductive resin layer 8 on the base substrate 1 by plating. The plating is preferably performed based on electroless plating by immersing the base substrate 1 in a plating solution. The plating may be copper plating or nickel plating, but is not limited thereto. After the plating, the plated substrate is subject to a cleaning process by such as water washing using water or proper water solution. With this process, a laminate structure can be obtained in which the conductive resin layer 8 and the metal film layer 9 are laminated on the surface of the transparent conductive film 12 as shown in FIGS. 4C and 4D.

A part, which corresponds to a region other than the auxiliary electrodes 10, of each of the conductive resin layer 8 and the metal film layer 9 is then removed through such as photolithography and etching techniques. The conductive resin layer 8 and the metal film layer 9 are etched out in a manner that the substrate insertion grooves 13 are formed. With this process, it is possible to form the auxiliary electrodes 10 each of which has a laminate of the conductive resin layer 8 and the metal film layer 9 divided in a middle region thereof as shown in FIGS. 4E and 4F.

It is preferable to perform a cleaning process after formation of the auxiliary electrodes 10. The cleaning process may be water washing using water or proper water solution. The cleaning process preferably includes acid treatment. Excess amount of resin and the like, which is adhered on the surface of the transparent conductive film 12 (i.e., region other than the auxiliary electrodes 10), can be removed by the acid treatment.

After formation of the auxiliary electrodes 10, the organic EL element 5 is then formed. The organic EL element 5 can be formed like the embodiment of FIG. 3 (first embodiment).

Finally, the opening edge 11 of the opposed substrate 6 is inserted in the substrate insertion grooves 13 and then is bonded to the auxiliary electrodes 10 so that the organic EL element 5 is housed in the concave portion 6a of the opposed substrate 6. The opposed substrate 6 can be bonded with proper adhesive material. The adhesive material preferably has moisture-proof property, and may be fritted glass. It is notable that, in a region of the base substrate 1 where the auxiliary electrodes 10 are not formed, the opening edge 11 of the opposed substrate 6 is bonded to the transparent conductive film 12 or directly to the base substrate 1, and thus there is a concern that a gap may be generated between the opposed substrate 6 and the base substrate 1 (and between the opposed substrate 6 and the transparent conductive film 12) caused of absence of the auxiliary electrode 10. In the embodiment, the gap is preferably filled with the adhesive material. The concave portion 6a of the opposed substrate 6 may be filled with a sealant resin to encapsulate the organic EL element 5. In this configuration, the opposed substrate 6 may be bonded with the sealant resin.

The organic EL lighting device of the embodiment shown in FIG. 2 can be obtained with the above described method. The organic EL lighting device manufactured by the above described method has advantages that: electric conductivity can be improved by the auxiliary electrode 10; the metal film layer 9 can be tightly adhered by the conductive resin layer 8; and moisture permeation into the organic EL element 5 can be blocked by the block structure 20.

### Third Embodiment

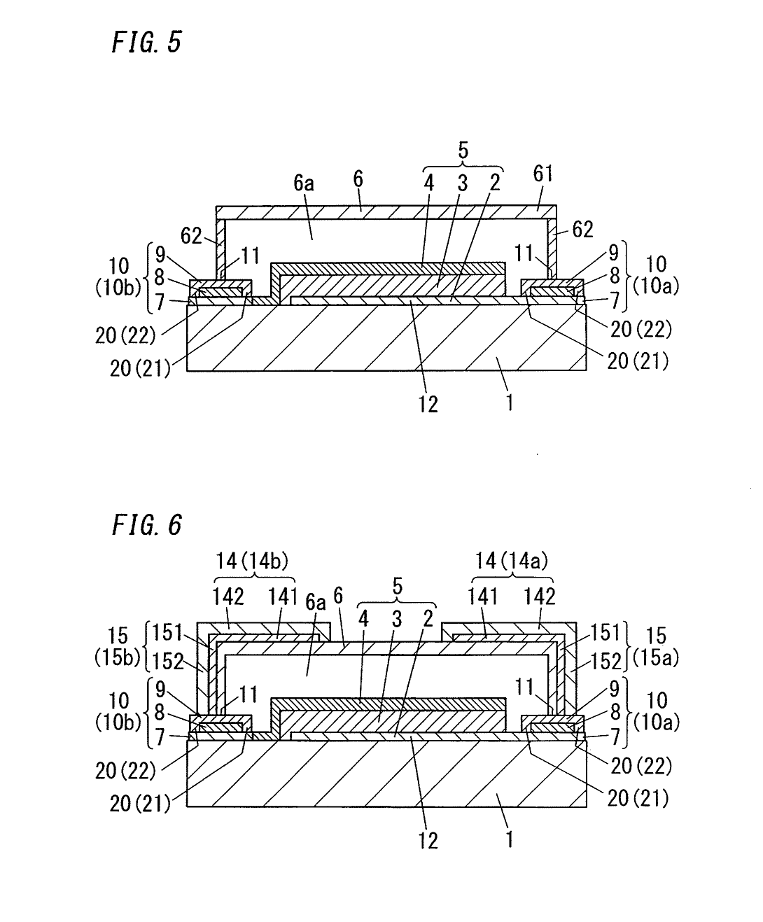

FIG. 5 shows an organic EL lighting device according to an embodiment. The organic EL lighting device in the embodiment has the substantially same configuration with the first embodiment, except for the structure in an opposed substrate 6.

The opposed substrate 6 of the embodiment is composed of a plate member 61 shaped like a planar plate and a lateral wall member 62 prepared separately from the plate member 61. The opposed substrate 6 is formed by bonding the plate member 61 to a side (the upper side in FIG. 5) of the lateral wall member 62 shaped like a rectangular frame. A concave portion 6a is formed as a space surrounded by the plate member 61 and the lateral wall member 62. The opposed substrate 6 of the embodiment is made of material having small moisture permeability. Thus, it is possible to suppress moisture permeation through the opposed substrate 6 from outside.

The lateral wall member 62 is made of resin having moisture-proof property. The lateral wall member 62 may contain moisture-proof material. The lateral wall member 62 is preferably made of high-viscosity resin. In case of forming the lateral wall member 62 from the high-viscosity resin, the lateral wall member 62 can be formed by a process including steps of: applying the resin on the auxiliary electrode 10 using a dispenser so that the resin has a desired height; and curing the resin. The lateral wall member 62 is preferably made of resin having viscosity. With using the viscous resin, even in a case where there is a step on a surface of the base substrate 1 side (e.g., there is a step between the auxiliary electrode 10 and a transparent conductive film 12)), the step can be filled with the resin material when the lateral wall member 62 is formed. The lateral wall member 62 is preferably made of UV curable resin, for ease of adjusting the height thereof.

The plate member 61 is made of glass, metal, resin having moisture-proof property, or the like. The plate member 61 may be a glass substrate shaped like a planar plate (e.g., a cover glass).

The plate member 61 may be bonded to the lateral wall member 62 by a process including steps of: disposing the plate member 61 on the resin material of the lateral wall member 62; and curing the resin material. For example, in a case where the lateral wall member 62 is made of UV curable resin, the plate member 61 can be bonded to the lateral wall member 62 by a process including steps of: applying the UV curable resin on the auxiliary electrode 10; disposing the plate member 61 on the UV curable resin; and irradiating the UV curable resin with ultraviolet light to thereby cure the lateral wall member 62, so that the plate member 61 is bonded to the lateral wall member 62.

Alternatively, the plate member 61 may be bonded to the lateral wall member 62 with proper adhesive material. The adhesive material preferably has moisture-proof property, and may be fritted glass.

An inner space (the concave portion 6a of the opposed substrate 6) surrounded by the lateral wall member 62 and the plate member 61 may be filled with a sealant resin to encapsulate an organic EL element 5. Examples of the sealant resin include epoxy resin and acrylic resin containing moisture absorbent member and buffer material.

In the embodiment, the concave portion 6a of the opposed substrate 6 can be easily filled with the sealant resin by a process including steps of: applying the resin as the material of the lateral wall member 62 so that the resin is shaped like a frame; dropping the sealant resin in a space surrounded by the resin (i.e., the lateral wall member 62) so that the space is filled with the sealant resin; and disposing the plate member 61 on the sealant resin.

The organic EL lighting device according to the embodiment can reduce production cost, since the opposed substrate 6 having the concave portion 6a on the center thereof can be made without using a glass in which a recess is formed (such as a glass substrate used for the first and second embodiments). Additionally, it is easy to fill the concave portion 6a with the sealant resin.

Method of bonding the opposed substrate 6 to the base substrate 1 side is not limited to the above described process. For example, the opposed substrate 6 can be bonded to the base substrate 1 side with proper adhesive material (such as fritted glass) after bonding the plate member 61 and the lateral wall member 62 to each other.

In the embodiment, the auxiliary electrode 10 has the same configuration with the first embodiment. Alternatively, the auxiliary electrode 10 may have the same configuration with the second embodiment.

### Fourth Embodiment

An organic EL lighting device according to an embodiment is described with reference to FIGS. 6, 7, and 8.

The organic EL lighting device according to the embodiment has the substantially same configuration with the device according to the first embodiment, and further includes electrode terminals (electrode pads) 14 and side conductors 15. The electrode terminals 14 and the side conductors 15 each have electric conductivity.

In the organic EL lighting device, as shown in FIG. 6, each of the electrode terminals 14 is formed on a rear side of an opposed substrate 6. Each of the electrode terminals 14 is connected to a corresponding metal film layer 9 through a side conductor 15 which is formed on a lateral surface of the opposed substrate 6. Each of the side conductors 15 includes an adhesion layer 151.

Each of the electrode terminals 14 is formed on the rear side (the upper side in FIG. 6) of the opposed substrate 6. The electrode terminals 14 include: a first electrode terminal 14a electrically connected to a first auxiliary electrode 10a; and a second electrode terminal 14b electrically connected to a second auxiliary electrode 10b. Each of the electrode terminals 14 preferably has: a bonding layer 141 formed in close contact with the opposed substrate 6; and a metal layer 142 formed on the bonding layer 141. The bonding layer 141 is adhered to the opposed substrate 6, and to thereby enhance adhesion between the metal layer 142 and the opposed substrate 6.

The bonding layer 141 is made of proper resin having high adhesion, and may be made of acrylic resin or epoxy resin. The bonding layer 141 can be made by applying the resin material on the opposed substrate 6 through a dispenser or immersion process.

The metal layer 142 can be made of proper metal material having high electric conductivity. In view of productivity, the metal material preferably has a property suitable for plating and has high electric conductivity. Examples of the metal material include Cu and Ni. It is preferable that the metal layer 142 is formed on only a region corresponding to the bonding layer 141. The metal layer 142 having the above described structure can be formed by a process including steps of: applying a catalyst solution for plating to the bonding layer 141; and plating the bonding layer 141 (through such as electroless plating).

Each of the side conductors 15 is formed on a lateral surface of the opposed substrate 6 so that each of the side conductors 15 connects an auxiliary electrode 10 to a corresponding electrode terminal 14. The side conductors 15 includes: a first side conductor 15a which connects the first auxiliary electrode 10a to the first electrode terminal 14a; and a second side conductor 15b which connects the second auxiliary electrode 10b to the second electrode terminal 14b. Each of the side conductors 15 has an electrically conductive metal layer 152 and the adhesion layer 151. The adhesion layer 151 is formed in close contact with the opposed substrate 6, and to thereby enhance adhesion between the metal layer 152 and the opposed substrate 6.

The adhesion layer 151 is made of proper resin having high adhesion, and may be made of acrylic resin or epoxy resin. The adhesion layer 151 can be made by applying the resin material to the opposed substrate 6 through a dispenser or immersion process.

The metal layer 152 can be made of proper metal material having high electric conductivity. In view of productivity, the metal material preferably has a property suitable for plating and has high electric conductivity. Examples of the metal material include Cu and Ni. It is preferable that the metal layer 152 is formed on only a region corresponding to the adhesion layer 151. The metal layer 152 having the above described structure can be formed by a process including steps of: applying a catalyst solution for plating to the adhesion layer 151; and plating the adhesion layer 151 (through such as electroless plating).

Preferably, each of the electrode terminals 14 is formed integrally and continuously with a corresponding side conductor 15. In detail, each pairs of the bonding layer 141 and the adhesion layer 151 may be made of the same material and formed integrally, and each pairs of the metal layer 142 and the metal layer 152 may be made of the same material and formed integrally.

With the organic EL lighting device according to the embodiment, each of the electrode terminals 14 is formed on the rear side of the opposed substrate 6. With this configuration, protruded amount of each auxiliary electrode 10 protruded from the opposed substrate 6 (width of the auxiliary electrode 10 in a right-left direction in FIG. 6) can be minimized to the extent of a thickness of the side conductor 15. Accordingly, the lighting device can have a small width (have a slim bezel).

Even in a case where the lighting devices are arranged side by side in right-left direction of FIG. 6, each of the lighting devices can be easily connected to an external power source through a well-known wire bonding technique or the like. In this case, it is possible to reduce occurrence of short circuit between bonding wires, in comparison with a case where the electrode terminal 14 is not provided.

The electrode terminals 14 and the side conductors 15 can be made by plating, and therefore production cost can be reduced.

The electrode terminals 14 and the respective side conductors 15 can be formed integrally by a process including steps of: forming a resin layer, from which the bonding layers 141 and the adhesion layers 151 are formed, on a whole surface of the opposed substrate 6; forming a metal film, from which the metal layers 142 and the metal layers 152 are formed, on a whole surface of the resin layer; and removing a part, which corresponds to a region other than the electrode terminals 14 and the side conductors 15, of the resin layer and the metal layer, through photolithography and etching techniques. With this process, the electrode terminals 14 (the first electrode terminal 14a and the second electrode terminal 14b) and the side conductors 15 (the first side conductor 15a and the second side conductor 15b) can be formed in a lump.

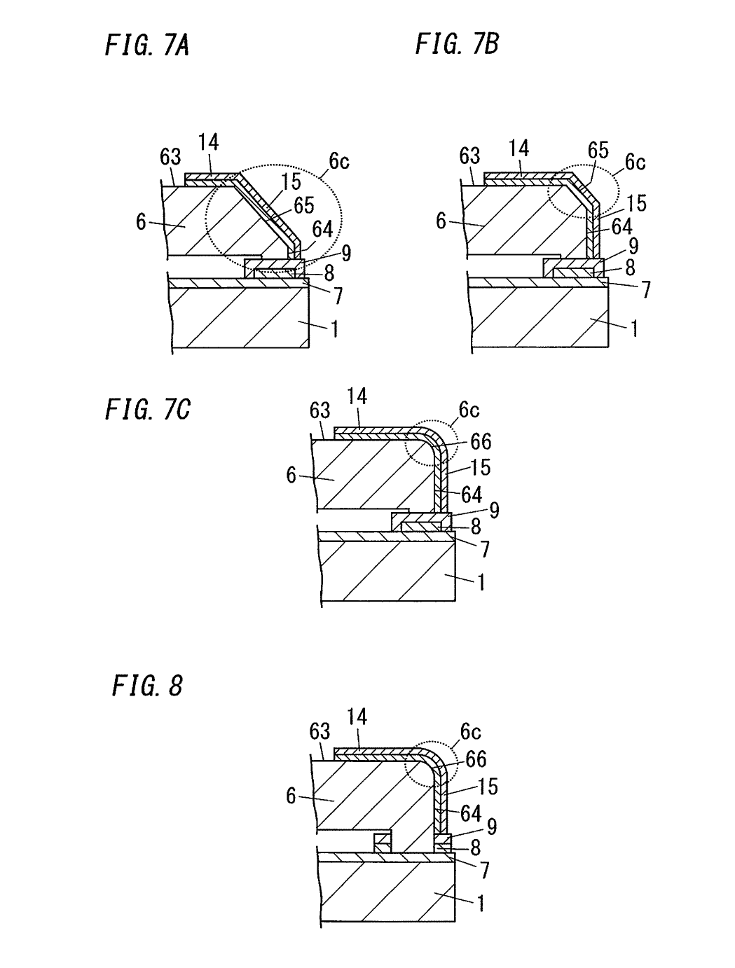

In the embodiment, it is preferable that the opposed substrate 6 is formed, on an edge of the rear side thereof, with a chamfered structure 6c so as to moderate an angle of the edge, as shown in FIGS. 7A, 7B and 7C. In other words, the opposed substrate 6 is formed, on parts thereof on which the metal layers 141, 151 are formed, with the chamfered structure 6c. In the embodiment, a corner in circumference of the rear side of the opposed substrate 6 is chamfered through polishing process, and thereby the chamfered structure 6c is formed.

In the embodiment, the opposed substrate 6 has obtuse angled portions, and the metal layer is formed on the obtuse angled portions. With this configuration, it is possible to reduce occurrence of disconnection of the conductor formed on the opposed substrate 6.

In each of the structures shown in FIGS. 7A and 7B, the opposed substrate 6 has: an upper surface 63; a lateral surface 64; and an inclined surface 65 formed between the upper surface 63 and the lateral surface 64. The upper surface 63 and the inclined surface 65 take the form of an obtuse angle, and the lateral surface 64 and the inclined surface 65 take the form of an obtuse angle. With the structure shown in FIG. 7A, because the angled portions are comparatively distant from each other, it is possible to reduce occurrence of disconnection. With the structure shown in FIG. 7B, it is possible to maintain a thickness, namely strength, at the edge of the opposed substrate 6 and also reduce occurrence of disconnection.

In the structure shown in FIG. 7C, chamfered structure 6c is formed of a curved surface 66 formed between the upper surface 63 and the lateral surface 64. With this structure, it is possible to maintain the strength of the opposed substrate 6 and also reduce occurrence of disconnection.

In the embodiment, the electrode terminals 14 and the side conductors 15 are provided to the organic EL lighting device according to the first embodiment. Alternatively, technical feature of the embodiment can be applied to the organic EL lighting device according to the second embodiment or the third embodiment, as shown in FIG. 8.

1. An organic electroluminescent lighting device, comprising:
a base substrate;
an organic electroluminescent element formed on a surface of the base substrate, the organic electroluminescent element comprising an optically-transparent first electrode, a light-emitting layer, and a second electrode facing the first electrode with the light-emitting layer interposed therebetween; and
an opposed substrate, the organic electroluminescent element formed on the surface of the base substrate being sealed with the opposed substrate which has a concave portion in a center thereof and which is placed opposite to the base substrate, wherein
the organic electroluminescent lighting device further includes an auxiliary electrode which is formed on the surface of the base substrate so that the auxiliary electrode is across an opening edge of the opposed substrate, the auxiliary electrode comprising a transparent conductive layer made of optically-transparent electrode material, a conductive resin layer made of electric conductive resin, and a metal film layer made of metal having higher electric conductivity than that of the material of the transparent conductive layer, which are stacked in this order on the surface of the base substrate, and
the auxiliary electrode is formed with a block structure configured to block moisture permeation through the conductive resin layer into the organic electroluminescent element from outside.

2. The organic electroluminescent lighting device according to claim 1, wherein the opposed substrate is formed of a plate member shaped like a planar plate and a lateral wall member which is made of resin and prepared separately from the plate member, so that the concave portion is formed between the plate member and the lateral wall member.

3. The organic electroluminescent lighting device according to claim 1, wherein the block structure has a structure in which the metal layer is formed so as to cover at least one lateral of the conductive resin layer.

4. The organic electroluminescent lighting device according to claim 1, wherein the block structure has a structure in which each of the metal layer and the conductive resin layer is divided by the opening edge of the opposed electrode.

5. The organic electroluminescent lighting device according to claim 1, wherein
an electrode terminal is formed on a rear side of the opposed substrate,
the electrode terminal is connected with the metal film layer through a side conductor formed on a lateral side of the opposed substrate, and
the side conductor includes an adhesion layer.

6. The organic electroluminescent lighting device according to claim 5, wherein the opposed substrate is formed, on an edge of the rear side of the opposed substrate, with a chamfered structure so as to moderate an angle of the edge.

7. A method for manufacturing the organic electroluminescent lighting device according to claim 1, comprising a step of forming the auxiliary electrode that comprises:
a resin layer application step of applying the material of the conductive resin layer to the transparent conductive layer formed on the base substrate so that the material is applied to a region where the auxiliary electrode is to be formed, thereby forming the conductive resin layer; and
a metal film plating step of forming the metal film layer on a surface of the conductive resin layer by plating.
